(19) United States
(12) Patent Application Publication
(10) Pub. No.: US 2014/0246088 A1
(43) Pub. Date: Sep. 4, 2014

(54) THIN FILMS AND PREPARATION PROCESS THEREOF

(71) Applicant: RELIANCE INDUSTRIES LIMITED, Mumbai, Maharashtra (IN)

(72) Inventors: Uday Agarwal, Mumbai (IN); Swanand Patil, Pune (IN)

(73) Assignee: RELIANCE INDUSTRIES LIMITED, Mumbai, Maharashtra (IN)

(21) Appl. No.: 14/353,227

(22) PCT Filed: Oct. 23, 2012
(86) PCT No.: PCT/IN2012/000699

§ 371 Date: Apr. 21, 2014

(30) Foreign Application Priority Data
Oct. 24, 2011 (IN) 2993/MUM/2011

(51) Int. Cl. H01L 31/18; B21C 1/00; H01L 31/032; B21B 1/00; H01L 31/0352; H01L 31/0272

(52) U.S. Cl. CPC H01L 31/18; H01L 31/0352; H01L 31/0272; H01L 31/0322; H01L 31/0326; B21B 1/00; B21C 1/00
USPC 136/256; 136/264; 136/265; 72/379.2; 29/428; 427/76; 427/74

(57) ABSTRACT

A process for the preparation of a thin film having at least one layer of a predetermined thickness not exceeding 5 microns is provided such that the integrity of the thin film is preserved. The process for the preparation of such a thin film comprises the step of rolling at least one sheet. The step of rolling is preceded by a step of stacking at least one sheet on a substrate having a predetermined thickness. The process of stacking preferably includes the step of bonding at least one sheet to a substrate. The sheet is a metal, alloy or a combination thereof, the metal and the alloy being of metals selected from the groups IB, IIB, IIIA, IVA, IVB, VB and VIB.

### FIELD OF THE DISCLOSURE

The present disclosure relates to thin films.

### DEFINITIONS

The expression ‘sheets’ used in the specification refers to but is not limited to homogenous/heterogeneous layers, conducting material including wires and grids/arrays/mesh thereof, these sheets having at least one of a planar and non-planar configuration.

The expression ‘stacking’ used in the specification refers to but is not limited to arranging metal or alloy sheets one over the other, pouring and spreading molten metals or alloys or paste of metals or alloys to form layers of sheets, wherein the expression sheet is defined as above.

The expression ‘substrate’ used in the specification refers to at least one layer of flexible metallic/alloy sheet, wherein the expression sheet is defined as above.

The expression ‘metalworking’ used in the specification refers to pressure based non-destructive thinning processes including but not limited to rollpressing, drawing, ironing and calendaring of sheets and excludes processes like etching, scratching, sputtering and other physical, chemical, light-induced or sound-induced destructive processes that operate by way of removing material, wherein the expression sheet is defined as above.

These definitions are in addition to those expressed in the art.

### BACKGROUND

Thin films are typically employed as active layers of photovoltaic solar cells that capture sun light and convert it to electricity, often in combination with other layers as electron or hole acceptors, as well as conducting layers. Some examples of the active layers are amorphous silicon, cadmium telluride, copper indium gallium selenide (CIGS), copper indium selenide (CIS), copper zinc tin sulfide (CZTS), titanium dioxide, silicon dioxide and zinc sulphide. The efficiencies (electric energy produced: incident solar energy) of these cells is substantially less than 50%, more often less than 20%, and considerably less than theoretically estimated maximum optical efficiency for the corresponding cell type. Though thin-film solar cells are attractive because of their reduced material requirement (and thus often low cost), particularly in case of thin-film solar cells, lower than theoretical maximum efficiencies are attributed to a number of factors including contact resistance between layers, shunt resistance of the film and occurence of deleterious void formation during film growth.

Thin-film technology offers a wide variety of choices in terms of device design and fabrication. The preferred methods for obtaining thin films include a choice of a wide variety of substrates, for instance, flexible, rigid, metal or insulator substrates which are then coated using various deposition techniques such as vapor deposition (PVD, CVD, ECD, plasma-based, hybrid), evaporation, sputtering, or screen printing/jet-printing of solutions, spin or dip-coating, electro-deposition and the like.

Thin-film formation tends to be the chief challenge for manufacturers as the highest performing thin film solar cells are required to satisfy a difficult combination of suitable deposition method, operation at elevated temperatures and high vacuum, extended deposition time, managing controlled compositions and reactions, arrangements of four elements, Na doping and large grain size. For instance, ink-based technology for deposition of CIGS employs deposition of metal salts or nanoparticles on a substrate, followed by subjecting the substrate deposited with metal salts or nanoparticles to a high temperature in order to remove the organic components or sintering of nanoparticles. The properties of CIGS that may change within a film and from one film to the other and expected to affect device performance are band gap (Eg), carrier lifetime (t), carrier density (p), carrier mobility (μ), and front and rear surface recombination velocities (SF and SR). Additionally, loss of expensive metals as wastage during deposition is also associated with these conventional methods Again, these methods often require prior preparation of films (for instance during sputtering, methods involving deposition of nanoparticles, salts or their solutions in substantially pure form).

Conventional thin films are limited in thickness by their preparation process that is intended to preserve the integrity of thin films, typically having thickness below 10 microns and generally finding application in thin film solar cells. Cracks/pinholes in thin films are not desirable in applications such as solar cells wherein such deformities affect the operational efficiency of the device.

Some endeavors have been made to overcome this drawback. One of them being pressure rolling Cu—In alloy at elevated temperatures to form a foil of thickness 20 microns as disclosed in Japanese Patent No. 4127483. Further processing of these foils using ultrasonic waves is carried out to reduce the thickness below 20 microns. This two stage process is necessitated in order to preserve the integrity of the thin film.

Again the United States Patent Application 20060163329 discloses the process of press bonding. However, it is necessarily preceded by the processes of activation and sputtering in order to obtain thin films which are then subsequently bonded using the process of press bonding.

Such additional precursory processes add to the complexity of the process of manufacturing thin films besides making it economically less viable.

Roll bonding processes to obtain multilayer sheets have been explored in some prior art. One of them being a disclosure in U.S. Pat. No. 6,267,830 that relates to the use of roll bonding for obtaining a 5-ply composite metal product for the manufacture of cookware. This process is limited by its application to products that do not require very thin films typically having thickness below 10 microns, for instance cookware, coins, and the like. Other disclosures, for instance United States Patent 20120017969 again disclose the process of roll bonding. However, this disclosure again finds application in the manufacture of substrates used in solar cells which are not limited by the need for an extremely thin film. Hence this disclosure does not provide a withstanding solution for obtaining thin films having thickness at least below 10 microns, especially thin films finding application in solar cells as absorbing layers, without compromising on the integrity of the film.

Therefore, there is felt a need to provide a simple, cost effective and efficient process to overcome the shortcomings associated with the hitherto reported processes and others known in the art and obtain thin films without compromising the integrity of the film.

### OBJECTS

Some of the objects of the present disclosure aimed to ameliorate one or more problems of the prior art or to at least provide a useful alternative are described herein below:

An object of the present disclosure is to provide thin films.

Another object of the present disclosure is to provide a process for preparation of thin films comprising at least one layer of sheet.

Still another object of the present disclosure is to provide a process for the preparation of cost effective thin films comprising at least one layer of sheet having a predetermined thickness below 5 microns.

Yet another object of the present disclosure is to provide an efficient process for preparation of thin films comprising at least one layer of sheet.

Still one more object of the present disclosure is to provide thin films wherein integrity of the film is maintained.

Further, an objective of the present disclosure is to provide a simple process of preparation of thin films that enhances the production rate.

Other objects and advantages of the present disclosure will be more apparent from the following description which is not intended to limit the scope of the present disclosure.

### SUMMARY

In accordance with the present disclosure, there is provided a process for the preparation of a thin film, the process comprising the step of metalworking at least one sheet to obtain the thin film having at least one layer of a predetermined thickness not exceeding 5 microns, wherein the integrity of the thin film is preserved, the sheet being a sheet of metal, alloy or a combination thereof, the metal and the alloy being of metals selected from the groups IB, IIB, IIIA, IVA, IVB, VB and VIB.

Typically, in accordance with the present disclosure, the step of metalworking is preceded by a step of stacking at least one of the sheets on a substrate having a predetermined thickness.

Preferably, the step of metalworking is preceded by a step of stacking at least one of the sheets on a substrate exhibiting a thickness at least 5 times a minimum thickness exhibited by any one of the sheets.

Additionally, in accordance with the present disclosure, the step of stacking is performed on at least one of the sheets having a thickness of at least 10 microns.

Optionally, in accordance with an embodiment of the process of the present disclosure, the step of stacking the sheets further comprises a step of bonding the sheets to each other or bonding at least one of the sheets to the substrate

Furthermore, the step of pressure rolling is performed at ambient temperature or at an elevated temperature.

Additionally, at least one of the layers formed by the process described herein above is subjected to at least one process selected from the group consisting of selenization, sulphurization and tellurization.

In accordance with the present disclosure, a thin film is provided that comprises at least one sheet of metal, alloy or a combination thereof, the metal and the alloy being of metals selected from the groups IB, IIB, IIIA, IVA, IVB, VB and VIB, the thin film characterized by at least one layer of a predetermined thickness not exceeding 5 microns, the integrity of the thin film being preserved, wherein at least one layer is obtained by a process of metalworking.

Typically, in accordance with the present disclosure, the thin film as described herein above includes at least one layer obtained by the process of metalworking being preceded by a process of stacking the sheet on a substrate having a predetermined thickness, wherein preferably the substrate exhibits a thickness at least 5 times a minimum thickness exhibited by any one of the sheets.

Preferably, in accordance with the present disclosure, the thin film described herein above includes at least one layer obtained by the process of metalworking being preceded by a process of stacking performed on at least one of the sheets having a thickness of at least 10 microns.

Further, in accordance with the present disclosure, the thin film obtained by the process described herein above finds application in a solar cell as an absorber layer or a contact/conducting layer. Such a solar cell may be comprised in a solar module.

### DETAILED DESCRIPTION

A non-limiting embodiment and the various features and advantageous details thereof are explained herein below in the following description. Descriptions of well-known components and processing techniques are omitted so as to not unnecessarily obscure the embodiment herein. The examples used herein are intended merely to facilitate an understanding of ways in which the embodiment herein may be practiced and to further enable those of skill in the art to practice the embodiment herein. Accordingly, the examples should not be construed as limiting the scope of the embodiment herein.

Conventionally, the process of obtaining thin films and further processing of the same for solar cell applications involve high temperature and high vacuum. Such processes, besides requiring precursor processing steps, may also result in cracks or pinholes in the obtained thin film, thus compromising the integrity of the films.

The present disclosure envisages a thin film and its manufacturing process to overcome the drawbacks of the prior art.

In accordance with the present disclosure, the manufacturing process of a thin film comprises the step of metalworking at least one sheet to obtain a thin film having at least one layer of predetermined thickness not exceeding 5 microns wherein the integrity of said thin film is preserved.

The sheets are either metal sheets or alloys of metals or a combination thereof wherein the metals are selected from the groups IB, IIB, IIIA, IVA, IVB, VB and VIB.

In accordance with a preferred embodiment of the process of the present disclosure, the metalworking process is a rollpressing process achieved typically by employing machines like rolling mills.

This rollpressing process typically involves passing of sheets through rollers of a rolling mill wherein the gap between the rollers is adjusted to exert adequate pressure on the sheet for obtaining thin films of desired thickness.

Sheets that are subjected to rollpressing as described herein above are not required to be restricted to any particular thickness. Typically, conventional processes for obtaining a thickness of the order of 10 microns are known to provide thin films wherein its integrity is preserved. To further thin, such thin films without compromising on its integrity, the rollpressing process as described above is preferably preceded by a step of stacking at least one of the sheets on a substrate having a predetermined thickness. Such a substrate exhibits a thickness at least 5 times a minimum thickness exhibited by any one of the sheets.

The step of rollpressing is typically conducted at ambient temperature. Optionally, rollpressing can be conducted at elevated temperatures or may require intermediate annealing steps to facilitate thickness reduction during rollpressing.

Although the step of rollpressing results in bonding of the stacked plurality of sheets, preferably, at least one sheet is bonded to the substrate by any bonding process known in the art including roll bonding, application of an adhesive, cast bonding, roll casting, explosion bonding, centrifugal casting and the like besides spray deposition, electrodeposition, melting in-situ and the like, prior to roll pressing. Alternatively, a plurality of sheets may be bonded to each other by any bonding process known in the art.

Absorbing layers in a photovoltaic cell are typically stacked on a substrate or a substrate coated with a contact layer like molybdenum.

In accordance with an embodiment of the process of the present disclosure, thin films obtained by the process of the present disclosure are subjected to methods like selenization, sulphurization and tellurization when such films are used as absorbing layers in photovoltaic solar cells.

In accordance with an alternate embodiment of the process of the present disclosure, a thin contact/conducting layer on a substrate is obtained by the process described herein above.

In accordance with yet another alternate embodiment of the process of the present disclosure, the thin films thus obtained find application as a contact/conducting layer in photovoltaic solar cells.

In accordance with the present disclosure, formation of the thin film involves a plurality of layers including substrate, contact/conducting layer, absorber layer and the like. The initial layering sequence of absorber layer constituents in the stack and the final film can be suitably designed to minimize diffusion with the substrate layer/reduce crack formation.

Although the explanation or additional embodiments are aimed at solar cell applications of the thin films obtained by the process of the present disclosure, other applications of these films are included in the scope of the present disclosure.

It is thus apparent from the aforementioned description of the process of the present disclosure that the process of thinning down thin films to a desired thickness with at least one layer having a thickness below 5 microns is achieved by rollpressing technique which is relatively a very fast and non-destructive method as compared to the processes known in the art including CVD, PVD, spraying, electrodeposition and the like, thus making it a much cheaper alternative to the methods known in the art.

### Test Data

A layered precursor structure required for solar cell was prepared by roll-bonding process. Thickness reduction of such bonded structure can be carried out using a two-high, four-high or any other cluster rolling mill. Continuous feeding and collection of strips on spools can be done by methods known in prior art (U.S. Pat. No. 3,269,004) where tension and feed speeds provide additional control variables.

In an experimental setup, a two-high strip rolling mill from Buhler, Pforzheim (Model—VRW 105/32-100) was used for thickness reduction or bonding of about 1″ wide strip samples. Prior to bonding of metal layers, the relevant surfaces were freshly cleaned by abrasion with crimped wire wheel brush and degreased with acetone. In case of indium and tin metal layers, only a chemical cleaning was employed. While bonding, the cleaned strips were held together by seeping a very small drop of cyanoacrylate glue at the leading edge. Alternatively, fastening with thin wires can be employed. Initial strip length was typically 4″, and whenever the reduction resulted in strip length exceeding 12″, it was cut into 4″ lengths. The mill was operated at 100 cm/min.

Several experiments were conducted to test the process disclosed herein above.

### Experiment 1: Preparation of a Layered Composite Structure of Copper/Aluminum (Cu/Al)

One strip each of copper foil (23 μm thick) and aluminum sheet (0.4 mm thick) were reduced together 60% in a single rolling pass to obtain a well bonded, about 0.17 mm thick composite strip. Thickness of the composite strip was further reduced by passing it few times through a rolling mill with minimum gap maintained between the rolls to make the Cu/Al strip about 0.051 mm thick. The aluminum side of the composite strip was placed on an additional 0.4 mm thick aluminum strip and further reduced by 60% in a single pass to obtain 0.18 mm thick. Cu/Al composite strip with copper layer of about 1 μm.

### Experiment 2: Preparation of a Layered Composite Structure of Indium/Copper/Aluminum (In/Cu/Al)

A thin foil of copper of thickness of 23 μm was bonded to a 0.4 mm thick aluminum sheet in a single pass through a rolling mill with gap between the rolls maintained at 0.1 mm. The resulting copper/aluminum composite strip was about 0.18 mm thick (about 57% reduction in thickness) and copper foil was very well bonded to aluminum. The copper/aluminum composite strip was further passed through the rolling mill with minimum gap between the rolls to obtain a strip with thickness of about 0.10 mm (about 45% reduction). At this stage the thickness of copper was about 5.5 μm.

A thin layer of indium metal was bonded on the copper side of the above copper/aluminum composite strip. The length of the copper/aluminum strip was 50 mm while the indium piece used for bonding was 10 mm long, 60 μm thick and had the same width as that of the copper/aluminum strip. The strip with indium was passed through the rolling mill with minimum gap between the rolls. Due to the very soft nature of indium, the rolling resulted in spreading of indium on copper with thickness of indium being about 10 μm while copper thickness being about 4.5 μm. Thickness of indium and copper layer in the composite strip of indium/copper/aluminum was further reduced by adding additional 0.4 mm thick aluminum sheet on the aluminum side of the indium/copper/aluminum strip and passing through the rolling mill with minimum gap between the rolls.

In the final composite strip of indium/copper/aluminum, thickness of indium was about 1.6 μm while that of copper was about 0.7 μm. The composite strip thus prepared was used for further processing to make thin film solar cells of CuInS2 (CIS) or CuInSe2 (CISe) and the like.

### Experiment 3: Preparation of a Layered Composite Structure of Indium/Copper/Aluminum/Thick Copper (In/Cu/Al/Thick Cu)

The composite structure given in Experiment 2 showed cracks, perpendicular to the rolling direction in the copper layer. This may be due to the better malleability of aluminum than copper. To balance the stresses in the composite strip during the rolling process, thinner aluminum sheet was used and additional thick copper strip was bonded to the aluminum side to avoid the cracking in copper.

One strip each of 23 μm thick copper foil and 0.2 mm thick aluminum sheet were reduced together by 40% in a single rolling pass to obtain a well bonded 0.12 mm thick Cu/Al composite strip with about 14 μm thick copper layer.

The aluminum side of the Cu/Al composite strip was then placed onto 0.5 mm thick copper strip and further reduced by about 50% to obtain the Cu/Al/thick Cu composite strip. The top copper layer was about 6.75 μm thick.

A 100 μm thick indium foil was placed onto the thin copper side of the Cu/Al/thick Cu composite strip and passed through the rolling mill with minimum gap maintained between the rolls to obtain a well bonded In/Cu/Al/thick Cu composite strip with about 6 μm thick indium and about 4 μm thick copper layer. Thickness of the composite strip was further reduced by passing it through the rolling mill with minimum gap maintained between the rolls. The final composite strip had about 2 μm thick indium, about 1.3 thick copper and did not show any cracking of the thin copper layer.

### Experiment 4: Preparation of a Layered Composite Structure of Tin/Brass/Aluminum (Sn/Brass/Al)

The process similar to the one given in Experiment 2 can be used to make a composite structure of tin/brass/aluminum. Bonding surfaces of brass (Cu:Zn=63:37 wt %, thickness=50 μm) foil and aluminum sheet (0.4 mm thick) were abraded using crimped wire wheel brush and placed in contact with each other using a small drop of adhesive/glue at the leading edge. Bonding of the brass foil to aluminum sheet was achieved by passing them through a rolling mill with gap between the rolls maintained at a minimum. This resulted in about 20 μm thick brass bonded onto aluminum.

A thin layer of tin was then bonded onto the brass layer by spreading, similar to indium in Experiment 2. Rollpressing handles such spreading effectively by controlling the feed rates of the two layers. Tin used for bonding was 20 μm thick, 25 mm long and had same width as that of the brass/aluminum strip. The strip with tin was passed through the rolling mill with minimum gap between the rolls. Due to the soft nature of tin, the rolling resulted in spreading of tin on brass with thickness of tin about 10 μm while brass thickness was about 13 μm.

Further reduction in thickness of tin and brass was achieved by adding additional 0.4 mm thick aluminum sheet on the aluminum side of the previously rolled tin/brass/aluminum composite foil and passing the strips through the rolling mill with minimum gap between the rolls.

In the final composite strip of tin/brass/aluminum, thickness of tin was about 0.8 μm while that of copper was about 1 μm. The composite strip thus prepared was used for further processing to make thin film solar cells of Cu₂ZnSnS4 (CZTS) or Cu₂ZnSnSe4 (CZTSe) and the like.

Similar to indium rolling given in Experiment 2, non-affined rolling of tin was observed during the first rolling step while subsequent rolling was affined. Affined rolling of tin can be achieved even in the first rolling step by using tin foil with thickness of 10 μm or smaller.

### Experiment 5: Preparation of a Layered Composite Structure of Tin/Brass/Tin/Aluminum (Sn/Brass/Sn/Al) Using Brass Foil Electroplated with Tin

A 23 μm thick brass foil (Cu:Zn=63:37 wt %) was electroplated with total of 18 μm thick tin layer (9 μm thick tin plating on either side of the foil). 0.4 mm thick aluminum sheet was abraded on one side using crimped wire wheel brush and placed in contact with the tin-plated brass foil using a small drop of adhesive/glue at the leading edge. Roll bonding of the foil was then achieved by passing the foils through the rolling mill with gap between the rolls maintained at minimum. This resulted in well bonded foil with 7.5 μm thick brass and total of 5.9 μm thick tin (about 67% reduction in thickness) on a thick aluminum substrate.

Further reduction in thickness of tin and brass was achieved by adding additional 0.4 mm thick aluminum sheet on the aluminum side of the previously rolled tin/brass/tin/aluminum composite foil and passing the strips through the rolling mill with minimum gap between the rolls. This process was repeated to reduce the thickness of brass to 1 μm and that of tin to 0.8 μm (i.e. 0.4 μm on each side of brass).

The composite strip thus prepared was used for further processing to make thin film solar cells of CZTS or CZTSe and the like.

### Experiment 6: Preparation of Layered Composite Structures Given in Experiments 1, 2, 4 and 5 on Steel

The process of individual structures given in Experiments 1, 2, 4 and 5 were duplicated by using a 1 mm thick steel substrate instead of aluminum. Steel used in the process can be AISI 304, 316, 430 or similar.

### Experiment 7: Making of a Thin Film Solar Cell of Cu₂S Using the Composite Foil Prepared in Experiments 1 and 6

Sulfurization Process: The composite foils of Cu/Al (Experiment 1) or Cu/Steel (Experiment 6) were sulfurized in flowing H₂S gas (5% in N₂) or using sulfur powder in a closed vial purged with nitrogen gas for 30 min at 500 oC to obtain Cu₂S layer on aluminum or steel, respectively.

CdS Deposition: A thin layer of CdS was deposited onto the Cu₂S layer using chemical bath deposition (CBD). In a typical process cadmium sulfate, ammonia and de-ionized water were mixed at room temperature and the solution was heated to 70° C. with continuous stirring. When the solution attains the desired temperature, samples were immersed into the solution and after 5 minutes pre-heated thiourea solution was added into the solution. Typical concentrations of precursors in the solution were 0.001 M cadmium sulfate, 0.002 M thiourea and 2.68 M ammonia. The samples were removed from the solution after 20 min of CdS deposition, washed with de-ionized water and then dried in air. The dried samples were heated under nitrogen atmosphere for 15 min at 200° C.

Samples Testing: Open-circuit voltage (V_{oc}) generated by the cells was measured using a digital multimeter (Model: CIE 122) under D-65 (Day-light) illumination in a cabinet (LabTech Engineering Company Ltd.; Model: 301-70). Samples were kept on a clean copper foil to make contact with the substrate (Al or steel) while a small area point contact to the front CdS layer was made by using a gold-coated spring-loaded connector (Protectron Electromech Pvt. Ltd.). Reversibility of the voltage between zero (Source OFF) and measured voltage (under D-65 light) was confirmed by repeatedly switching the light source ON and OFF.

Results: Sample prepared on aluminum gave V_{oc} of about 20 mV under D-65 light.

The lower V_{oc} was perhaps due to the absence of front transparent conducting layer, weak contact between the substrate and the copper foil as well as weaker illumination (D-65) compared to the standard AM 1.5 G condition used for the testing. Nevertheless, the generation of V_{oc} indicates the feasibility of the rolling process to make solar PV and improvements can be made to obtain better results.

### Experiment 8: Making of a Thin Film Solar Cell of Cu₂Se Using the Composite Foil Prepared in Experiments 1 and 6

Selenization Process: The composite foil of Cu/Al (Experiment 1) or Cu/Steel (Experiment 6) were selenized using selenium pellets in a closed vial purged with nitrogen gas for 1 h. at 500° C. to obtain Cu₂Se layer on aluminum or steel, respectively. The selenized samples were then dipped in 0.2% bromine solution in methanol (vol/vol) for 15 s to remove excess selenium deposited on it during the selenization process, washed with de-ionized water and then dried in air.

A thin layer of CdS was deposited onto the Cu₂Se layer by CBD and tested for V_{oc} as per the procedure given in Experiment 7.

Results: Samples prepared on aluminum gave V_{oc} of about 100 mV under D-65 light.

### Experiment 9: Making of a Thin Film Solar Cell of CuInS₂ (CIS) Using the Composite Foil Prepared in Experiments 2, 3 and 6

Sulfurization Process: The composite foils of In/Cu/Al (Experiment 2), In/Cu/Al/thick Cu (Experiment 3) or In/Cu/Steel (Experiment 6) were sulfurized in flowing H₂S gas (5% in N₂) or using sulfur powder in a closed vial purged with nitrogen gas for 1 h at 500° C. to obtain CIS layer on aluminum, aluminum/thick copper or steel, respectively.

A thin layer of CdS was deposited onto the CIS layer by CBD and tested for V_{oc} as per the procedure given in Experiment 7.

### Experiment 10: Making of a Thin Film Solar Cell of CuInSe₂ (CISe) Using the Composite Foil Prepared in Experiments 2, 3 and 6

Selenization Process: The composite foils of In/Cu/Al (Experiment 2), In/Cu/Al/thick Cu (Experiment 3) or In/Cu/Steel (Experiment 6) were selenized using selenium pellets in a closed vial purged with nitrogen gas for 1 h at 500° C. to obtain CISe layer on aluminum or aluminum/thick copper. Samples on steel were processed similarly but at 600° C. for 1 h. The selenized samples were then dipped in 0.2% bromine solution in methanol (vol/vol) for 15 s to remove excess selenium deposited on it during the selenization process, washed with de-ionized water and then dried in air. A thin layer of CdS was deposited onto the CISe layer by CBD and tested for V_{oc} as per the procedure given in Experiment 7.

Results: Samples prepared on aluminum gave V_{oc} of about 2 my while those on steel gave about 70-80 mV when tested under D-65 light.

### Experiment 11: Making of Thin Film Solar Cell of Cu₂ZnSnS4 (CZTS) Using the Composite Foils Prepared in Experiments 4, 5 and 6

The composite foils of Sn/Brass/Al (Experiment 4), Sn/Brass/Sn/Al (Experiment 5), Sn/Brass/Steel (Experiment 6) or Sn/Brass/Sn/Steel (Experiment 6) were sulfurized using the process given in Experiment 9 to obtain CZTS layer on aluminum or steel, respectively.

A thin layer of CdS was deposited onto the CZTS layer by CBD and tested for V_{oc} as per the procedure given in Experiment 7.

### Experiment 12: Making of a Thin Film Solar Cell of Cu₂ZnSnSe4 (CZTSe) Using the Composite Foils Prepared in Examples 4, 5 and 6

The composite foils of Sn/Brass/Al (Example 4), Sn/Brass/Sn/Al (Experiment 5), Sn/Brass/Steel (Experiment 6) or Sn/Brass/Sn/Steel (Experiment 6) were selenized using the process given in Experiment 10 to obtain CZTSe layer on aluminum or steel, respectively.

A thin layer of CdS was deposited onto the CZTSe layer by CBD and tested for V_{oc} as per the procedure given in Experiment 7.

Results: Samples prepared on steel gave V_{oc} of about 5 mV under D-65 light.

### Technical Advancements

The technical advancements offered by the present disclosure include the realization of:
a process for preparation of thin films comprising at least one layer of sheet;
a process for the preparation of cost effective thin films comprising at least one layer of sheet having a predetermined thickness below 5 microns;
an efficient process for preparation of thin films comprising at least one layer of sheet;
a simple process of preparation of thin films that enhances the production rate;
thin films; and)
thin films wherein integrity of the film is maintained.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

The use of the expression “at least” or “at least one” suggests the use of one or more elements or ingredients or quantities, as the use may be in the embodiment of the disclosure to achieve one or more of the desired objects or results.

The numerical values given of various physical parameters, dimensions and quantities are only approximate values and it is envisaged that the values higher or lower than the numerical value assigned to the physical parameters, dimensions and quantities fall within the scope of the invention unless there is a statement in the specification to the contrary.

Wherever a range of values is specified, a value up to 10% below and above the lowest and highest numerical value respectively, of said specified range, is included within the scope of the disclosure.

The foregoing description of the specific embodiments will so fully reveal the general nature of the embodiments herein that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of preferred embodiments, those skilled in the art will recognize that the embodiments herein can be practiced with modification within the spirit and scope of the embodiments as described herein.

1. A process for the preparation of a thin film, said process comprising the step of:
metalworking at least one sheet to obtain said thin film having at least one layer of a predetermined thickness not exceeding 5 microns, wherein the integrity of said thin film is preserved,
said sheet being a sheet of metal, alloy or a combination thereof, the metal and the alloy being of metals selected from the groups IB, IIB, IIIA, IVA, IVB, VB and VIB.

2. The process as claimed in claim 1, wherein said step of metalworking is preceded by a step of stacking at least one of said sheets on a substrate having a predetermined thickness.

3. The process as claimed in claim 1, wherein said step of metalworking is preceded by a step of stacking at least one of said sheets on a substrate exhibiting a thickness at least 5 times a minimum thickness exhibited by any one of said sheets.

4. The process as claimed in claim 2, wherein said step of stacking is performed on at least one of said sheets having a thickness of at least 10 microns.

5. The process as claimed in claim 2, wherein said step of stacking further comprises a step of bonding said sheets to each other.

6. The process as claimed in claim 2, wherein said step of stacking further comprises a step of bonding at least one of said sheets to said substrate.

7. The process as claimed in claim 1, wherein said step of metalworking is performed at a predetermined temperature.

8. The process as claimed in claim 1, wherein at least one of said layers is subjected to at least one process selected from the group consisting of selenization, sulphurization and tellurization.

9. A thin film comprising at least one sheet of metal, alloy or a combination thereof, the metal and the alloy being of metals selected from the groups IB, IIB, IIIA, IVA, IVB, VB and VIB, said thin film characterized by at least one layer of a predetermined thickness not exceeding 5 microns, the integrity of said thin film being preserved, said at least one layer being obtained by a process of metalworking.

10. The thin film as claimed in claim 9, wherein said at least one layer is obtained by said process of metalworking being preceded by a process of stacking said sheet on a substrate having a predetermined thickness.

11. The thin film as claimed in claim 9, wherein said at least one layer is obtained by said process of metalworking being preceded by a process of stacking said sheet on a substrate exhibiting a thickness at least 5 times a minimum thickness exhibited by any one of said sheets.

12. The thin film as claimed in claim 10, wherein said at least one layer is obtained by said process of metalworking being preceded by a process of stacking performed on at least one of said sheets having a thickness of at least 10 microns.

13. A solar cell obtained by using at least one thin film of claim 9 as an absorber layer.

14. A solar module comprising the solar cell as claimed in claim 13.

15. A solar cell obtained by using at least one thin film of claim 9 as a contact/conducting layer.

16. A solar module comprising the solar cell as claimed in claim 15.
